(19) United States
(12) Patent Application Publication
(10) Pub. No.: US 2025/0070045 A1
(43) Pub. Date: Feb. 27, 2025

(54) PACKAGED DEVICE WITH AIR GAP AND METHODS OF FORMING SAME

(71) Applicant: Taiwan Semiconductor Manufacturing Co., Ltd., Hsinchu (TW)

(72) Inventors: Ming-Tsu Chung, Hsinchu (TW); Yung-Chi Lin, Su-Lin City (TW); Yan-Zuo Tsai, Hsinchu (TW); Yang-Chih Hsueh, Hsinchu (TW)

(21) Appl. No.: 18/403,298

(22) Filed: Jan. 3, 2024

Related U.S. Application Data
(60) Provisional application No. 63/520,727, filed on Aug. 21, 2023.
(60) Provisional application No. 63/608,674, filed on Dec. 11, 2023.

(51) Int. Cl. H01L 23/00; H01L 23/482; H01L 23/498; H01L 25/065

(52) U.S. Cl. CPC H01L 23/562; H01L 23/4821; H01L 23/49816; H01L 23/49838; H01L 24/05; H01L 24/29; H01L 25/0652; H01L 2224/05009; H01L 2224/05025; H01L 2224/29009; H01L 2224/29025; H01L 2924/01029; H01L 2924/1431; H01L 2924/1435; H01L 2924/15311; H01L 2924/182; H01L 2924/351

(57) ABSTRACT

In a package device, wherein integrated circuit devices are bonded to a substrate, stress arising from mechanical strain, CTE mismatch, and the like can be alleviated or eliminated by incorporating stress buffering air gaps into a protective material, such as a gap fill oxide. The air gaps can be formed by tuning and changing deposition parameters during the deposition process and/or by tuning the size and placement of adjacent integrated circuit devices in the package, and/or by forming trenches in the protective material prior to the bonding process.

### PRIORITY CLAIM AND CROSS-REFERENCE

This application claims the benefit of U.S. Provisional Application No. 63/520,727, filed on Aug. 21, 2023, and entitled, “Semiconductor Structure with Air Gap,” and of U.S. Provisional Application No. 63/608,674, filed on Dec. 11, 2023, and entitled, “PACKAGED DEVICE WITH AIR GAP AND METHODS OF FORMING SAME,” which applications are hereby incorporated herein by reference.

### BACKGROUND

As integration density increases in the field of semiconductor devices, increased density in packaging is required. Differences in material properties, such as coefficients of thermal expansion (CTE) can cause performance and reliability problems for such packaged devices. As an example, when an integrated circuit die is bonded to a substrate and embedded within a protective material, such as an oxide, CTE mismatch between the protective material and other components of the package structure can cause stress, resulting in delamination in some cases and potentially debonding or cracking in some cases. What is needed therefore, is a structure and method to improve performance and reliability of package semiconductor devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of an exemplary package device embodiment.

FIGS. 2A through 2E are cross-sectional views of steps in a method manufacturing process embodiment.

FIG. 3 is a top down view of an exemplary embodiment package device.

FIGS. 4A through 4B and 5A through 5F are cross-sectional views of relevant steps in another method manufacturing process embodiment.

FIGS. 6A through 6D are cross-sectional views of steps in yet another method manufacturing process embodiment.

FIGS. 7A through 7E are top down views of exemplary package devices.

FIGS. 8A, 8B, and 8C are flow charts illustrating steps of manufacturing process embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

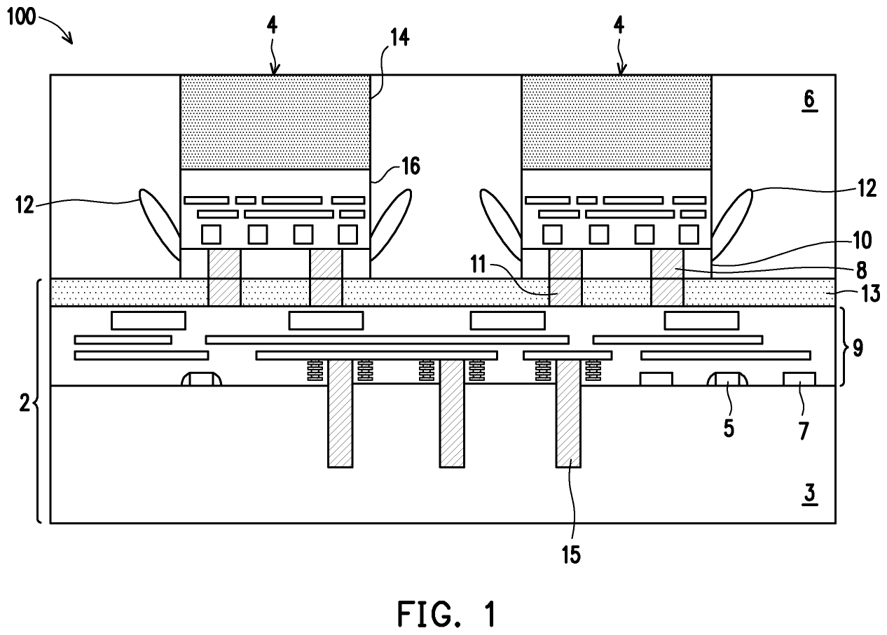

FIG. 1 illustrates an exemplary package device 100 which includes a bottom device 2 upon an upper surface of which has been bonded one or more integrated circuit devices 4. Each of integrated circuit devices 4 may be a logic die (e.g., application processor (AP), central processing unit, microcontroller, etc.), a memory die (e.g., dynamic random access memory (DRAM) die, hybrid memory cube (HBC), a static random access memory (SRAM) die, a wide input/output (wideIO) memory die, a magnetoresistive random access memory (mRAM) die, a resistive random access memory (rRAM) die, etc.), a power management die (e.g., power management integrated circuit (PMIC) dies), a radio frequency (RF) die, a sensor die, a micro-electro-mechanical-system (MEMS) die, a signal processing die (e.g., digital signal processing (DSP) die), a front-end die (e.g., analog front-end (AFE) die), a biomedical die, or the like. Each of integrated circuit devices 4 may also be a System-on-Chip (SoC) die, or the like.

Further details regarding exemplary integrated circuit devices 4 will now be provided. As shown, respective integrated circuit devices 4 include respective substrates 14. Active and/or passive devices, such as transistors, diodes, capacitors, resistors, etc., may be formed in and/or on substrates 14. The devices may be interconnected by respective interconnect structures 16, as is generally known in the art of integrated circuit devices. Interconnect structure 16 electrically connects the devices on substrate 14 to form one or more integrated circuits. Interconnect structure 16 may include one or more dielectric layers (for example, one or more interlayer dielectric (ILD) layers, intermetal dielectric (IMD) layers, or the like) and interconnect wirings or metallization patterns embedded in the one or more dielectric layers. The material of the one or more dielectric layers may include silicon oxide (SiOₓ, where x>0), silicon nitride (SiNₓ, where x>0), silicon oxynitride (SiOₓN_{y}, where x>0 and y>0), or other suitable dielectric material. The interconnect wirings may include metallic wirings. For example, the interconnect wirings include copper wirings, copper pads, aluminum pads or combinations thereof that are formed by one or more single damascene processes, dual damascene processes, or the like. The side of the integrated circuit device 4 comprising an exposed back side surface of substrate 14 may also be referred to subsequently as the back side of integrated circuit device 4.

Respective substrates 14 of the integrated circuit device 4 may include a crystalline silicon wafer. Substrate 14 may include various doped regions depending on design requirements (e.g., p-type substrate or n-type substrate). In some embodiments, the doped regions may be doped with p-type or n-type dopants. The doped regions may be doped with p-type dopants, such as boron or BF₂; n-type dopants, such as phosphorus or arsenic; and/or combinations thereof. The doped regions may be configured for n-type Fin-type Field Effect Transistors (FinFETs) and/or p-type FinFETs. In some alternative embodiments, substrate 14 may comprise an active layer of a semiconductor-on-insulator (SOI) substrate. Substrate 14 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used.

Bonding layer 10 may comprise a dielectric layer. Bonding pads 8 are embedded in bonding layer 10, and bonding pads 8 allow connections to be made to interconnect structure 16 and hence to devices on the substrate 14. The material of bonding layer 10 may be silicon oxide (SiOₓ, where x>0), silicon nitride (SiNₓ, where x>0), silicon oxynitride (SiOₓN_{y}, where x>0 and y>0), tetraethyl orthosilicate (TEOS), or other suitable dielectric material, and bonding pads 8 may comprise conductive pads (e.g., copper pads), conductive vias (e.g., copper vias), or combinations thereof. Bonding layer 10 may be formed by depositing a dielectric material over interconnect structure 16 using, e.g., a chemical vapor deposition (CVD) process (e.g., a plasma enhanced CVD process or other suitable process); patterning the dielectric material to form bonding layer 10 including openings or through holes; and filling conductive material in the openings or through holes defined in bonding layer 10 to form the bonding pads 8 embedded in bonding layer 10. In other embodiments, bonding pads 8 are formed first and bonding layer 10 is deposited around them.

Bottom device 2 may serve as a mechanical support structure for integrated circuit devices 4. In some instances, bottom device 2 further provides for electrical connection between respective integrated circuit devices 4, between integrated circuit devices 4 and active and/or passive components formed on or within bottom device 2, as well as between integrated circuit device 4 and other components that are external to package device 100. For instance in the embodiment illustrated in FIG. 1, bottom device 2 includes substrate 3, active devices (such as transistors, opto-electric sensors, MEMs devices, and the like) 5, passive devices (such as resistors, capacitors, inductors, and the like) 7, and a multi-layer interconnect structure 9. As an example, bottom device 2 may be an integrated circuit device manufactured using materials and formation processes similar to those used in forming integrated circuit devices 4. In other embodiments, bottom device 2 may be a semiconductor wafer, such as a bulk silicon wafer, a silicon-on-insulator (SOI) wafer, an interposer, a coreless substrate, a printed circuit board (PCB), a ceramic wafer, or the like. In the illustrated embodiment, bottom device 2 includes circuitry that contributes to the functioning of package device 100, but this is not a necessary feature of presently disclosed embodiments. As those skilled in the art will recognize, interconnect structure 9 includes a stack of conductive features, some of which are interconnected by conductive inter-layer vias, respective layers of which are embedded in respective layers of a stack of dielectric materials. Bottom device 2 also includes bonding pads 11 at a topmost surface of bottom device 2.

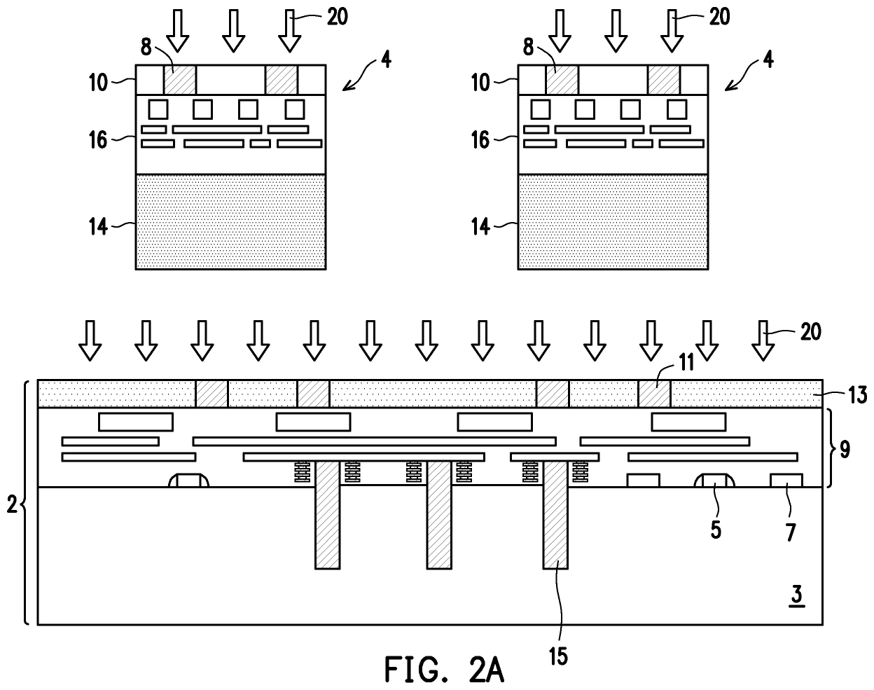

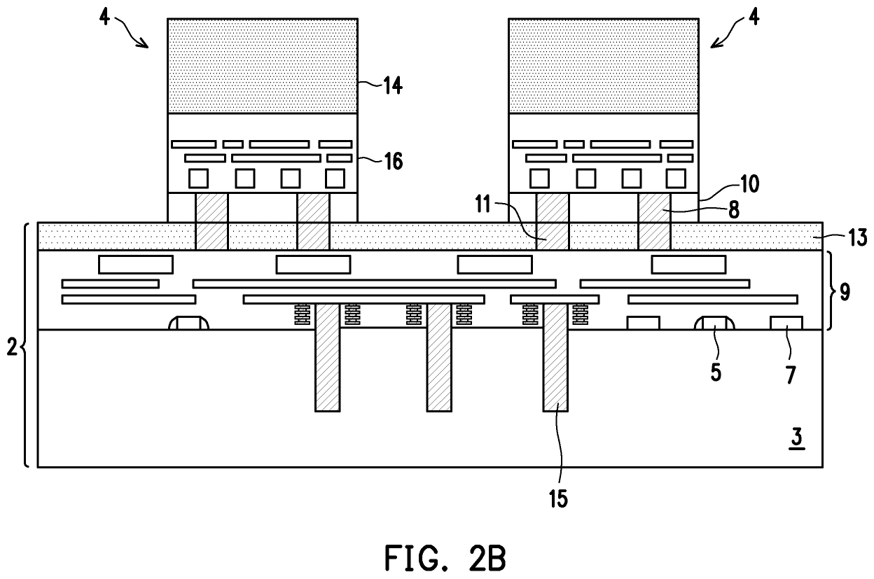

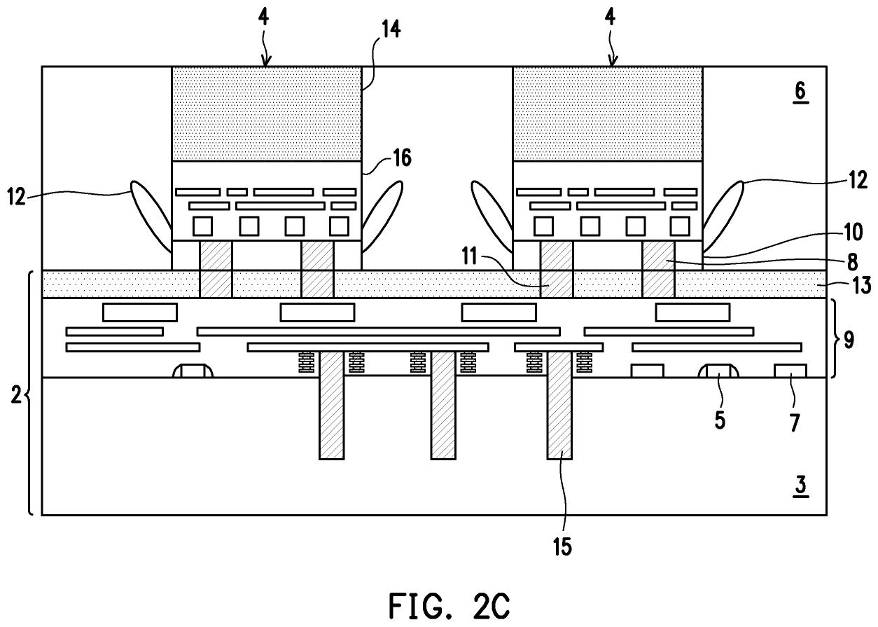

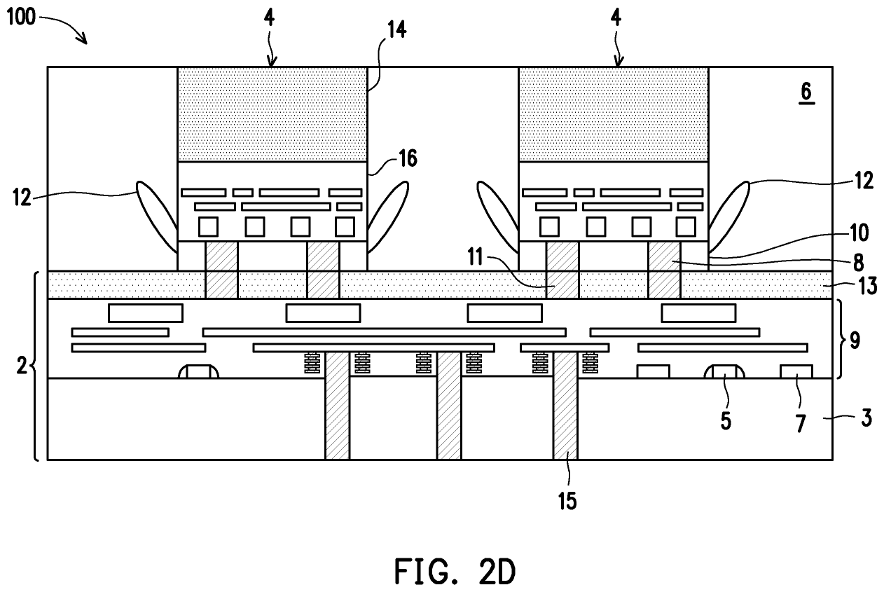

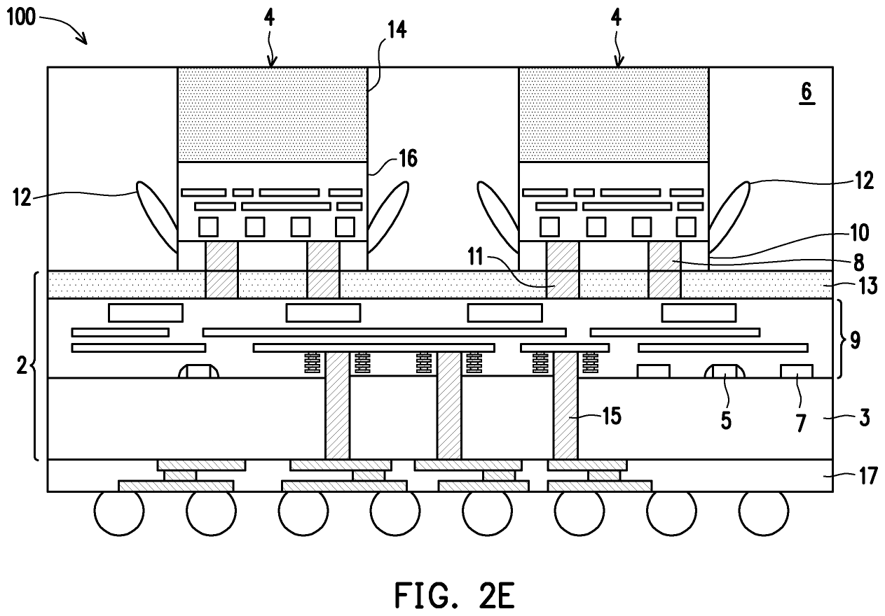

Also illustrated in FIG. 1 is bonding layer 13 disposed on interconnect structure 9, with bonding pads 11 being disposed in, and level with and exposed by bonding layer 13. These bonding pads 11 allow electrical connections to be made to the interconnect structure 9 and to integrated circuit devices 4 that are bonded to bottom device 2. In the illustrated embodiment, bottom device 2 further includes through substrate vias (TSVs) 15 which may be electrically connected to the metallization patterns in the interconnect structure 9 and/or active device 5 and/or passive devices 7. TSVs 15 may be formed by forming openings in substrate 3 by, for example, etching, milling, laser techniques, a combination thereof, or the like. A thin barrier layer (not shown) may be conformally deposited over the front side of substrate 3 and in the openings, such as by chemical vapor deposition (CVD), atomic layer deposition (ALD), physical vapor deposition (PVD), thermal oxidation, a combination thereof, or the like. The barrier layer may comprise a nitride, an oxynitride, such as titanium nitride, titanium oxynitride, tantalum nitride, tantalum oxynitride, tungsten nitride, combinations thereof, and/or the like. A conductive material is deposited over the thin barrier layer and in the openings. The conductive material may be formed by an electro-chemical plating process, CVD, ALD, PVD, a combination thereof, or the like. Examples of conductive materials are copper, tungsten, aluminum, silver, gold, a combination thereof, and the like. Excess conductive material and barrier layer may be removed from the front side of substrate 3 by, for example, chemical mechanical polishing. Thus, in some embodiments, TSVs 15 may comprise a conductive material and a thin barrier layer between the conductive material and substrate 3. In subsequent processing steps, substrate 3 may be thinned to expose the TSVs 15 so that electrical connection can be made thereto. After thinning of substrate 3 (see FIG. 2D), TSVs 15 provide electrical connection from a back side of substrate 3 to interconnect structure 9.

Finally, a protective material 6 is also illustrated in FIG. 1 encapsulating or surrounding integrated circuit devices 4 and also exposed portions of the top surface of bottom device 2. In some embodiments, protective material 6 is an oxide and may be referred to herein as a gap fill oxide, or GFOx, although other materials are within the contemplated scope of this disclosure. For instance, protective material 6 could comprise one or more layers of silicon oxide, silicon nitride, silicon oxynitride, polymer, molding compound, combinations thereof, or the like—provided that the material meets the requirements of the particular application, such as providing for electrical insulation, moisture protection, thermal management, mechanical protection, and the like. A particularly advantageous feature of embodiments described herein is the presence of air gaps within protective material 6, such as exemplary air gaps 12 illustrated in FIG. 1. As will be described in greater detail below, air gaps 12 can act as a stress buffer, relieving or otherwise ameliorating the effects of mismatch of coefficients of thermal expansion (CTE) between components of package device 100, such as between protective layer 6 and bottom device 2, for instance.

Additional details of an exemplary process for forming package device 100 will now be provided with reference to FIGS. 2A through 2C. Integrated circuit devices 4 are bonded to bottom device 20, for example, by metal-to-metal bonding contact pads 8 of respective integrated circuit devices 4 to corresponding bonding pads 11 of bottom device 2, and dielectric-to-dielectric bonding top dielectric layer 10 of respective integrated circuit devices 4 to bonding dielectric layer 13 of bottom device 2. In the illustrated embodiment of FIGS. 2A through 2C, although not a limitation on the present disclosure, integrated circuit devices 4 are disposed face down such that front sides of integrated circuit devices 4 face the bottom device 2 and back sides of the integrated circuit devices 4 face away from the bottom device 2. Integrated circuit devices 4 are bonded to bonding layer 13 on the front side of the bottom device 2 and bonding pads 11 in bonding layer 13. For example, bonding layer 10 of respective integrated circuit devices 4 may be directly bonded to bonding layer 13 of bottom device 2, and bonding pads 8 of respective integrated circuit devices 4 may be directly bonded to bonding pads 11 of bottom device 2. In an embodiment, the bond between bonding layer 10 and bonding layer 13 may be an oxide-to-oxide bond, or the like. The bonding process further directly bonds the bonding pads 8 of integrated circuit devices 4 to bonding pads 11 of the bottom device 2 through direct metal-to-metal bonding. Thus, electrical connection between integrated circuit devices 4 and bottom device 2 is provided by the physical connection of bonding pads 8 to bonding pads 11.

In an embodiment, the bonding process may start with preparing integrated circuit devices 4 and/or bottom device 2, for example, by applying a surface treatment 20 to one or more of bonding layer 10 or bonding layer 13, as schematically illustrated by FIG. 2A. The surface treatment may include a plasma treatment. The plasma treatment may be performed in a vacuum environment. After the plasma treatment, the surface treatment may further include a cleaning process (e.g., a rinse with deionized water, or the like) that may be applied to one or more of bonding layer 10 or bonding layer 13. Similarly, the preparation processes may be performed to bonding pads 8 and/or bonding pads 11.

The bonding process may then proceed to aligning bonding pads 8 to bonding pads 11, as shown in FIG. 2B. In some embodiments, the bonding process includes a pre-bonding step, during which the integrated circuit devices 4 are put in contact with the bottom device 2. The pre-bonding may be performed at room temperature (e.g., between about 21° C. and about 25° C.). The bonding process continues with performing an anneal, for example, at a temperature between about 150° C. and about 400° C. for a duration between about 0.5 hours and about 3 hours, so that the metal in bonding pads 8 (e.g., copper) and the metal of the bonding pads 11 (e.g., copper) inter-diffuses, and hence direct metal-to-metal bonds are formed. Although two integrated circuit devices 4 are illustrated as being bonded to the bottom device 2, other embodiments may include any number of integrated circuit devices 4 bonded to the bottom device 2.

After integrated circuit devices 4 are bonded to bottom device 2, protective material 6 is formed. In some embodiments, protective material 6 can be deposited to fully encapsulate integrated circuit devices 4 and then partially removed, e.g., through an etch back process, mechanical grinding and/or abrasion, chemical mechanical polishing, or the like, such that the top surface of protective material 6 is level with respective top surfaces of integrated circuit devices 4, as is shown in FIG. 2C. Also shown in FIG. 2C is the presence of air gaps 12 within protective material 6.

In the embodiment illustrated in FIG. 2C, air gaps 12 are formed along edges of respective integrated circuit devices 4 during the deposition of protective material 6. In an exemplary process, protective material 6 is silicon oxide deposited using a chemical vapor deposition (CVD) process wherein TEOS (tetraethyl orthosilicate) and oxygen are introduced as precursor gasses into a deposition chamber (not shown) to form a silicon oxide layer. Conventionally in semiconductor manufacturing processes, it is desired to deposit oxide layers in a consistent and uniform manner without gaps or other irregularities. Contrary to conventional wisdom, however, it has been determined that by maintaining a low pressure in the deposition chamber, less than 4 Torr, and by increasing the flow rate of TEOS precursor relative to oxygen precursor during deposition, air gaps can be intentionally introduced into the material as it is being deposited. Further, it has been discovered that formation of such an air gap, while contrary to conventional thinking about maintaining a uniform and regular layer of material, provides the advantageous feature of acting as a stress buffer by allowing localized deformation of the deposited material in response to stress, such as stress arising from CTE mismatch between the deposited material and other material and components of the package device. It has been further recognized that under the conditions of low pressure and an increased TEOS: oxygen flow ratio, air gap formation is substantially limited to regions adjacent and/or surrounding bottom edges of integrated circuit devices 4. Without being bound by any underlying theory, it is believed that the topographical irregularly, i.e. the step height between the top surface of bottom device 2 and the top surface of integrated circuit device 4, causes a localized region in which air gaps 12 will occur. This is particularly advantageous, as issues such as stress, delamination, and the like are particularly sensitive adjacent and around the edges of integrated circuit devices 4. As used herein, the term adjacent is used to denote a proximity that is sufficient to allow air gaps to buffer or otherwise offset stress that would otherwise cause deleterious effects (such as delamination, debonding, cracking, and the like) of the effected package component in the absence of the air gaps.

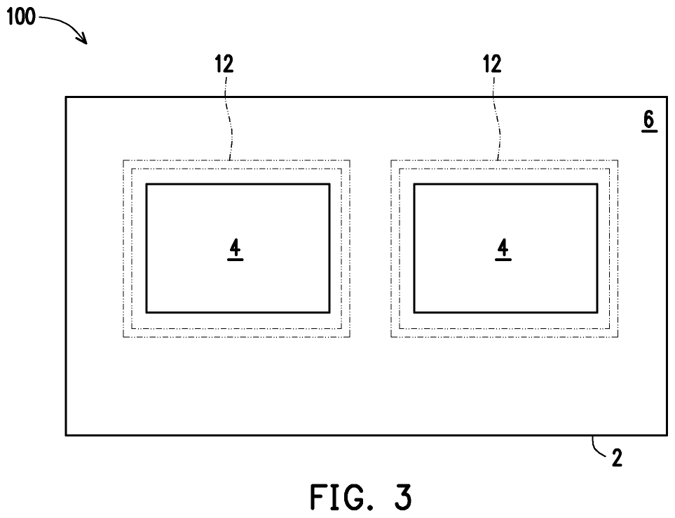

FIG. 1 and FIG. 2C illustrate respective air gaps 12 in cross-sectional view. FIG. 3 is a top down view of package device 100 and shows air gaps 12 from this perspective effectively surround respective integrated circuit devices 4. Air gaps 12 are shown in dotted line format in FIG. 2C, as protective material 6 will obscure the view of air gaps 12 in an actual product. As illustrated, because of topographical irregularities, such as the large step height from the upper surface of bonding layer 13 of bottom device 2 to the top of respective integrated circuit devices 4, air gaps 12 will be formed adjacent the sides of the respective integrated circuit devices 4, when the above-described deposition process is employed. It is believed that air gaps 12 act as a stress relieving buffer and hence reduce or eliminate the possibility of cracking, delamination, debonding, or the like that would otherwise arise from CTE mismatch and/or other mechanical forces acting upon protective material 6. For simplicity, air gap 12 is illustrated in FIG. 3 as a single, continuous gaps. In some embodiments, and depending upon the deposition parameters and the topography of the device being manufactured, air gap 12 might form a series or line of discontinuous gaps the generally follow the pattern illustrated in FIG. 3.

Continuing the description with FIG. 2D, this figures illustrates the results of an optional step of thinning back substrate 3 bottom device 2, which process is employed in those embodiments in which TSVs 15 are formed in bottom device 2. This thinning back process exposes the ends of TSVs 15, in addition to reducing the overall height of package device 100. Next, a backside interconnect structure 17 (FIG. 2E) is formed on the backside of bottom device 2, thus allowing for electrical interconnection between components that are external to package device 100 and circuitry on bottom device 2 as well as circuitry of integrated circuit devices 4.

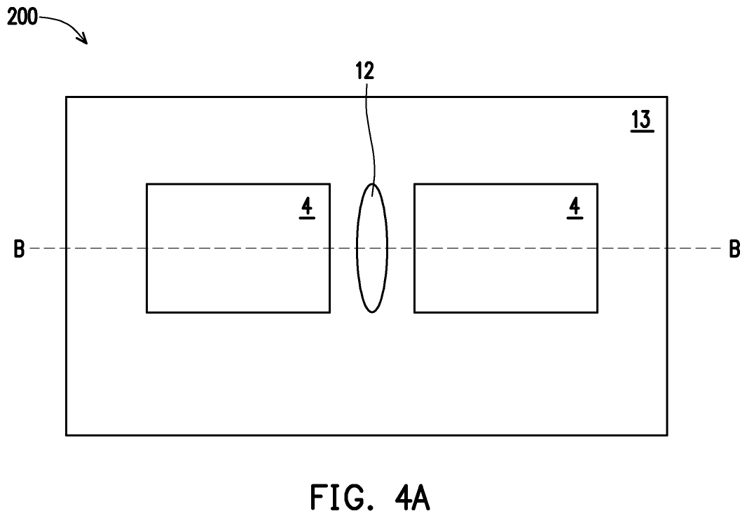

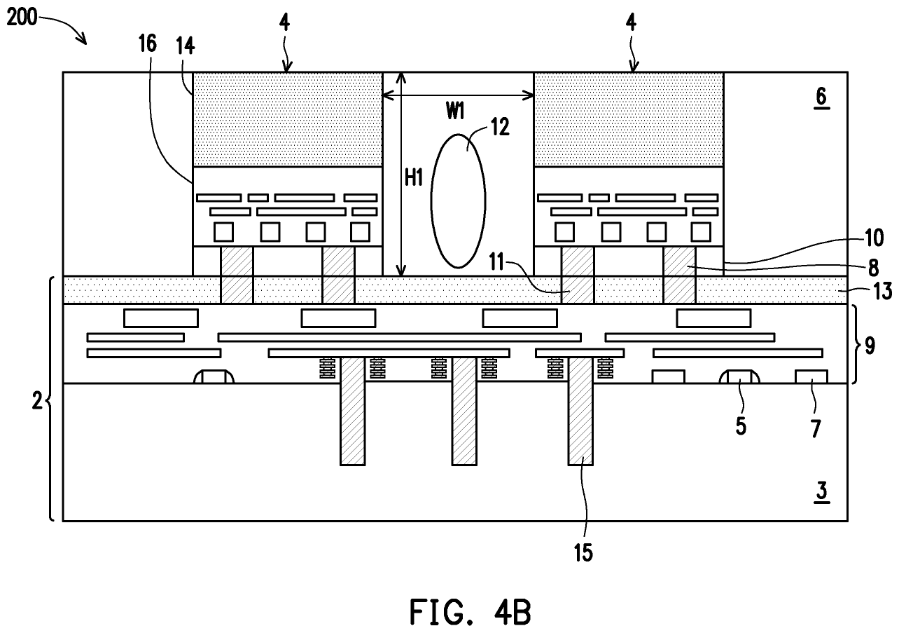

In another embodiment, air gap 12 can be formed to be confined to high stress regions between adjacent integrated circuit devices 4. This embodiment is illustrated with reference to FIGS. 4A and 4B, in which FIG. 4A is a top down view of exemplary package device 200 and FIG. 4B is a cross-sectional view of exemplary package device 200 along a cross-section indicated by dotted line B-B in FIG. 4A. Except as specifically indicated otherwise, the features and processes for manufacturing package device 200 of FIGS. 4A and 4B are the same those provided above for the embodiments illustrated in FIGS. 1 and 2A through 2E, which is further indicated by the use of common reference numerals for those features and processes that are common to the embodiments.

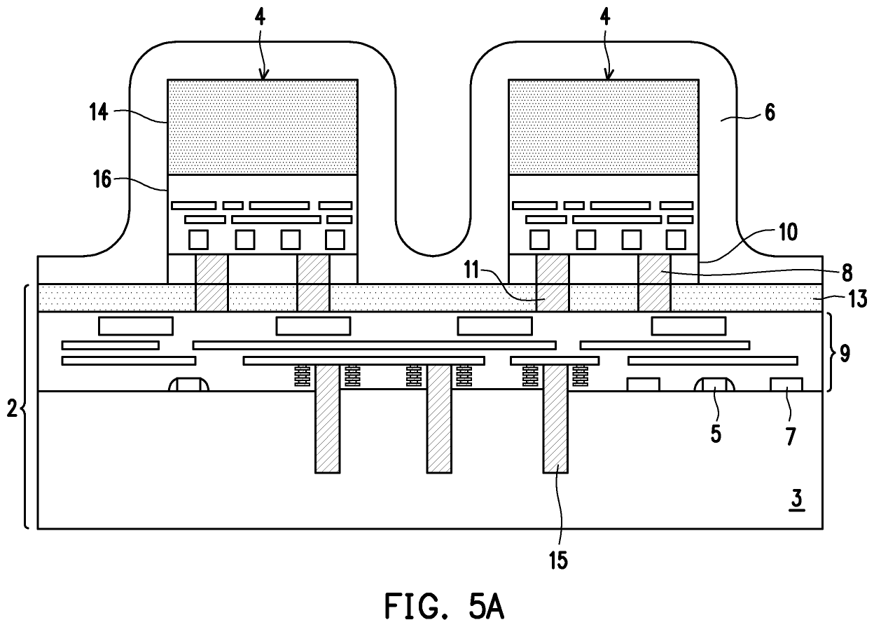

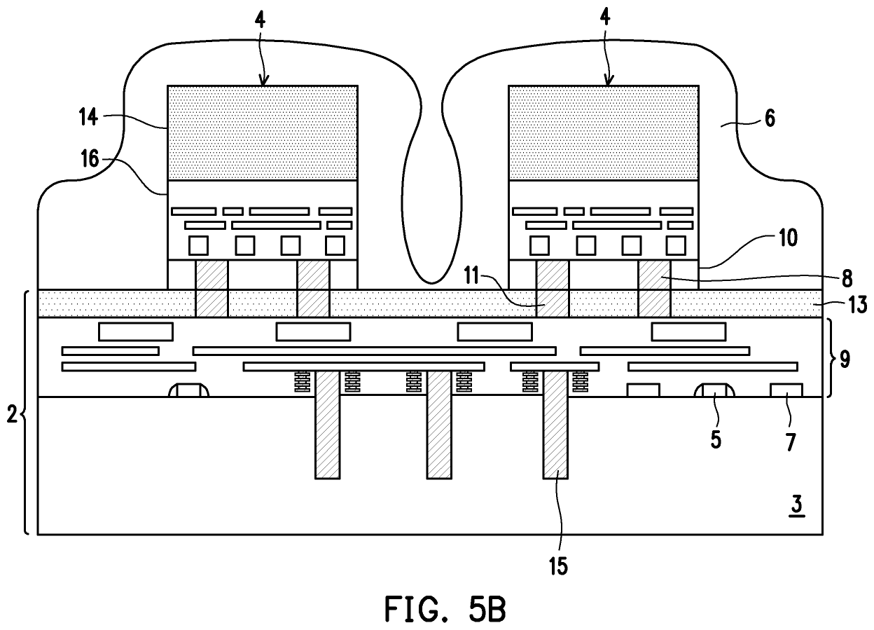

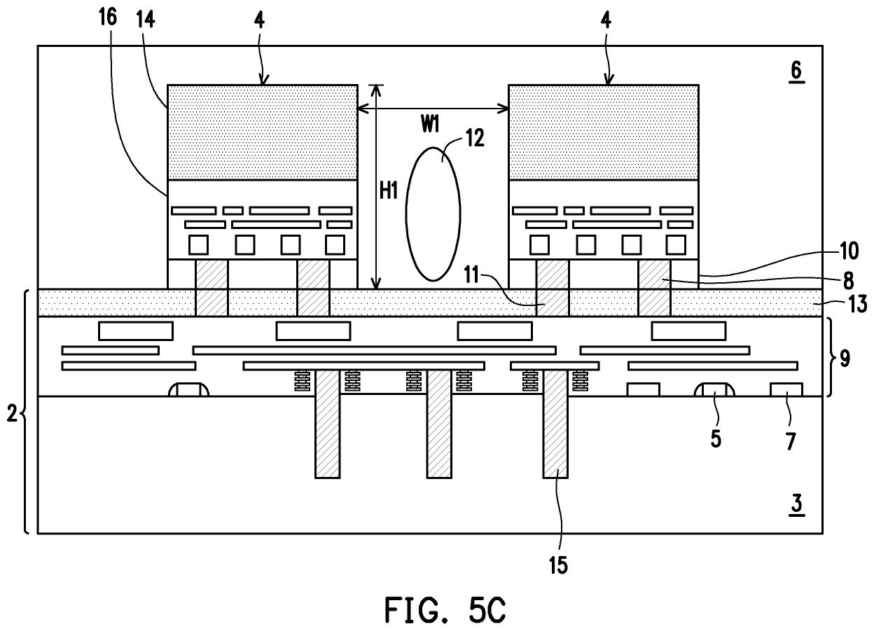

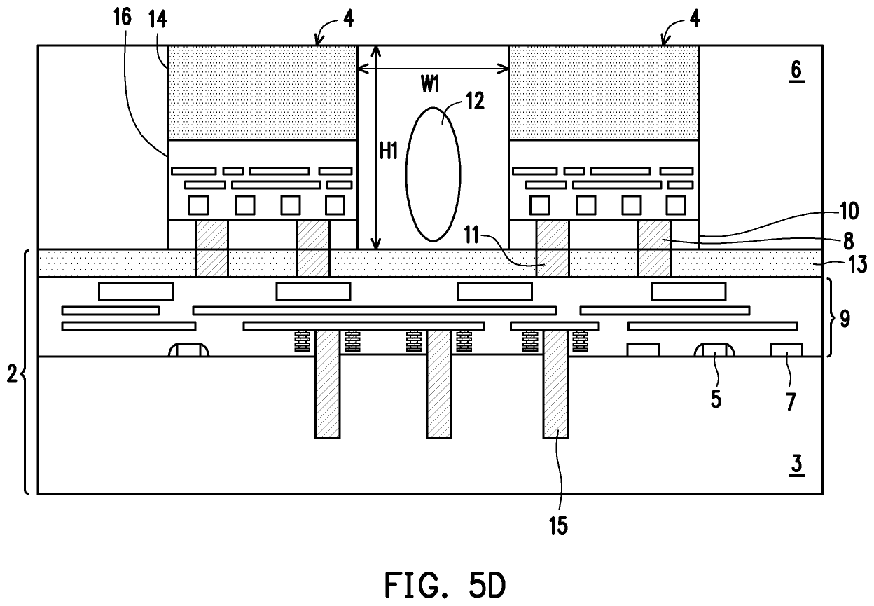

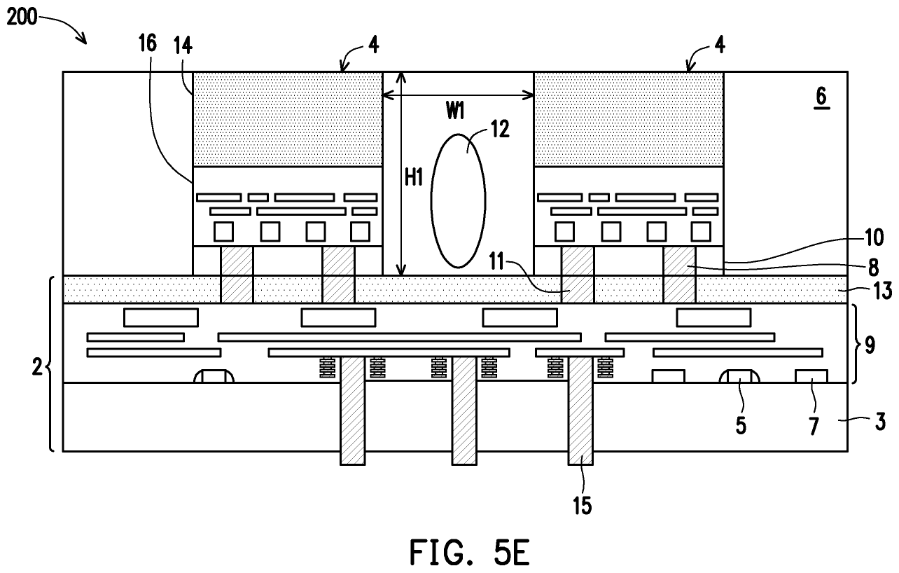

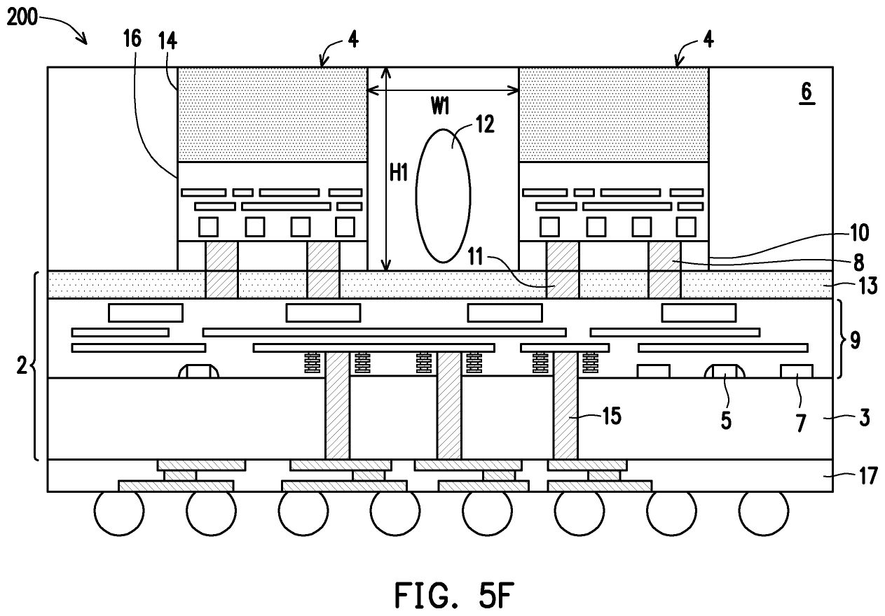

As illustrated in FIG. 4A, a single air gap 12 is formed between integrated circuit devices 4. This region may be an area subject to relatively high stress compared to other portions of package device 200, and this embodiment does not require, although it does not exclude, modifying or changing deposition parameters during the step of depositing protective material 6. In particular, it has been determined that air gap 12 can be formed interjacent respective integrated circuit devices 4 when an aspect ratio of the space between integrated circuit devices 4 is greater than about 1.5. Stated another way, and with reference to FIG. 4B, provided the ratio of the height of the respective integrated circuit devices 4 (H1) to the distance between nearest edges of the respective integrated circuit devices 4 (W1) is greater is greater than about 1.5, then air gap 12 will form. Without being tied to any particular underlying theory of operation, it is believed that protective material 6 will form on the surface of bonding layer 13 and between integrated circuit devices 4 in a somewhat conformal fashion. As a result, there will be formed a seam or a gap between sidewalls of the respective integrated circuit devices 4, as illustrated by FIG. 5A, which illustrates an intermediate phase of the deposition of protective film 6. A pinching off of this gap occurs as more of protective material 6 is deposited, as shown by FIG. 5B. As deposition continues material formed over the leftmost integrated circuit device 4 merges with material formed over the rightmost integrated circuit device 4, thus fully forming and sealing air gap 12, such as is shown by FIG. 5C. While other deposition processes for other material might result in the formation of a seam within the material, the conventional wisdom in the relevant art is that such seams, if they occur, are disadvantageous and should be prevented. Contrary to that conventional wisdom, it has been determined that tuning the height of respective integrated circuit devices 4 and the spacing between them can result in the formation of an advantageous air gap in the protective material, which serves to buffer against stress arising from CTE mismatch as well as other mechanical stresses. This approach to forming air gap 12 is considered particularly advantageous because air gap 12 will be spaced apart from and hence will not expose sides of integrated circuit devices 4. Furthermore, this formation process also ensures that air gap 12 will be spaced apart from and hence not expose the top surface of bottom device 2, or more specifically bonding layer 13. While not a limitation on the present disclosure, it is believed that air gaps 12 of up to 50 μm in size can be formed by this method.

FIG. 5C also illustrates that, in some embodiments, the gap between respective integrated circuit device 4 is overfilled and in fact protective material 6 is deposited above topmost surfaces of the integrated circuit devices 4. This is done to ensure that the integrated circuit device 4 are fully surrounded by protective material 6. Then, as illustrated in FIG. 5D, a process such as an etch-back process, mechanical grinding, a CMP process, or the like is preformed to planarize the top surface of protective material 6 and to make is level with top surfaces of respective integrated circuit devices 4. This overfilling and planarizing approach is not a necessary feature of any of the embodiments described herein, but this approach is equally applicable to the embodiments described with respect to FIGS. 2A through 2E, and to other embodiments described herein.

As with previously described embodiments, if TSVs 15 are formed within bottom device 2, wafer 3 of bottom device 2 can be thinned from the back side in order to expose ends of TSVs 15, as illustrated by FIG. 5E. Then, as illustrated in FIG. 5F, a backside interconnect structure 17 is formed to allow for electrical interconnection of package device 200 with external components.

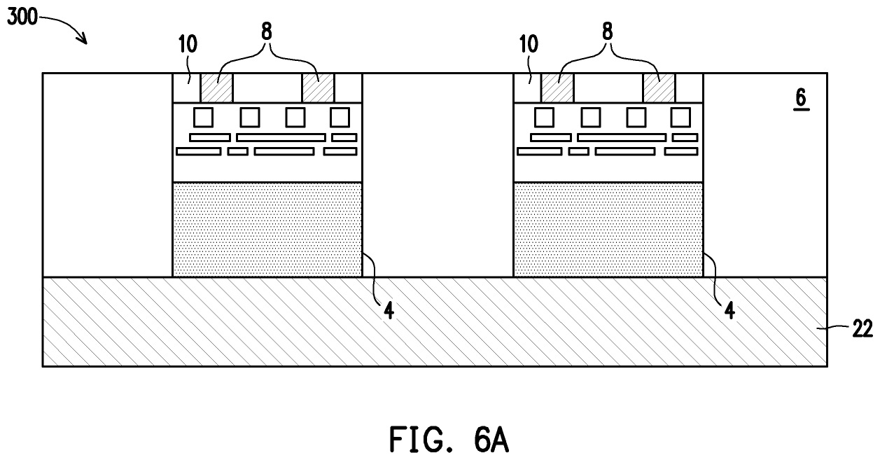

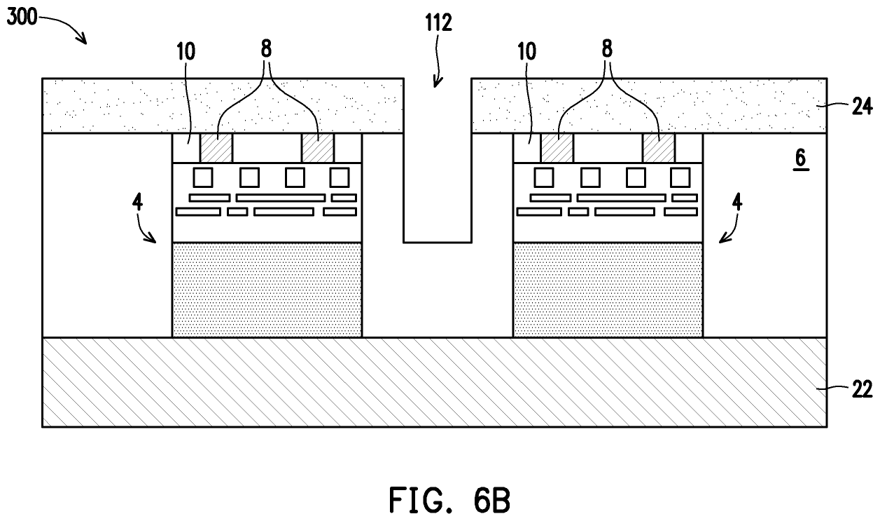

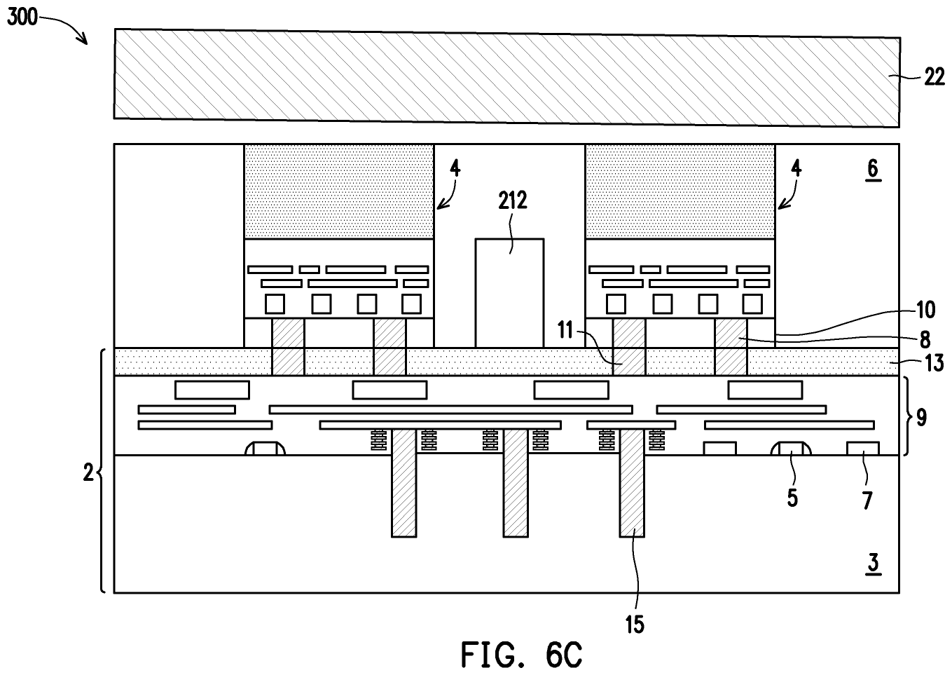

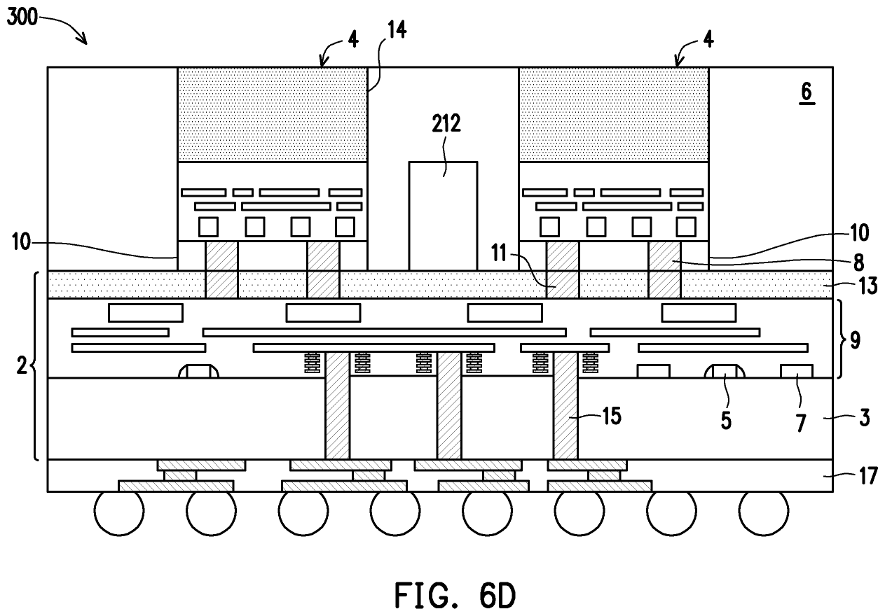

Yet another embodiment for forming a package device 300 having a stress buffering air gap is provided with reference to FIGS. 6A through 6D. In this embodiment, protective material 6 is formed before bonding integrated circuit devices 4 to bottom device 2. For instance, in the example illustrated in FIG. 6A, integrated circuit devices 4 are mounted onto a carrier substrate 22. Carrier substrate is temporary support structure that will be subsequently removed, as described below, and hence its composition is not particularly. Various carrier substrates are known in the art, including silicon wafers, ceramic substrates, quarts substrates, and the like. In some embodiments, two or more integrated circuit devices 4 are mounted to carrier substrate 22 using a temporary adhesive. In one embodiment, carrier substrate is made of a material that is substantially transparent to radiant energy of a particular wavelength range, and a temporary adhesive that loses its adhesive properties when subjected to radiant energy of the particular wavelength can be employed.

Regardless of the carrier substrate and adhesion technique employed, integrated circuit devices 4 are placed on carrier substrate 22 in an arrangement that matches the arrangement desired when integrated circuit devices 4 are bonded to bottom device 2, as will be described in greater detail below. In other words, the relative placement and spacing for integrated circuit devices 4, as they are temporarily bonded to carrier substrate 22 should match the desired placement and spacing of integrated circuit devices 4 when they are subsequently bonded to bottom device 2. Note that in this process, integrated circuit devices 4 are mounted onto carrier substrate in a face up configuration, meaning the backsides (wafer sides) of integrated circuit devices 4 are adhered to carrier substrate 22, leaving respective bonding layers 8 and respective bonding pads 10 unobstructed.

FIG. 6A also illustrates protective material 6 having been deposited onto carrier substrate s2 and surrounding integrated circuit devices 4. In this embodiment, protective material 6 can be deposited using conventional deposition processes and parameters, as air gap formation during the deposition process is not needed in this embodiment. In FIG. 6A, protective material 6 is shown as level and planar with top surfaces of integrated circuit devices 4. This could be the result of the deposition process. In other embodiments, however, protective material 6 can be deposited to overfill the gap between respective integrated circuit devices 4 and to cover respective integrated circuit devices 4 (such as illustrated in FIG. 5C) and then thinned back (using etch-back, mechanical abrasion, CMP, or the like).

FIG. 6B illustrates a process of forming a trench 112 in the top surface of protective material 6 after it has been deposited (and planarized in some embodiments). Trench 112 can be formed using a photolithography process wherein a mask layer 24 is formed atop protective material 6 and then patterned with an opening corresponding to trench 112. After patterning mask layer 24, protective material 6 is patterned using an appropriate etch process. In the case of a protective material made of silicon oxide, trench 112 can be formed, for example, using a wet etch process such as a buffered oxide etch (BOE) process involving HF etchant. Given the relatively large size of trench 112 (typically multiples of micrometers or tens of micrometers) and the relatively loose alignment tolerance for the location of trench 112, various types of etch processes could be employed to form trench 112, whether anisotropic or isotropic, a wet etch or a dry etch. One skilled in the art will appreciate that particular etch processes can be determined once informed by the present disclosure. In some embodiments, mask layer 24 is a photoresist material that can be deposited, photolithographically patterned, and then used as an etchant mask during the etch process. In other embodiments, mask layer 24 could be hard mask formed of silicon nitride or other material that is more resistant to the etch process, in which case a photolithographically patterned photoresist material (not shown) is formed over the hard mask in order to pattern mask layer 24.

Once trench 112 is formed in the top surface of protective material 6, integrated circuit devices 4, along with protective material 6, can be mounted onto bottom device 2, as shown in FIG. 6C. Note that in FIG. 6C, integrated circuit devices 4 are “flipped” relative to the orientation shown in FIG. 6A. This is so that integrated circuit devices 4 can be bonded to bottom device 2 in a face-to-face orientation, thus allowing bonding layer 10 of respective integrated circuit devices 4 to dielectric-to-dielectric bond with bonding layer 13 of bottom device 2, and to allow bonding pads 8 of respective integrated circuit devices 4 to form metal-to-metal bonds with respective bonding pads 11 of bottom device 2. Note that trench 112 becomes “sealed” when protective material 6 is mounted to bottom device 2, thus forming an air gap 212 (in some embodiments, protective material 6 will form a dielectric-to-dielectric bond with bonding layer 13 of bottom device 2). As also illustrated in FIG. 6C, once integrated circuit devices are bonded to bottom device 2, carrier substrate can be removed as it is no longer needed for mechanical support. Finally, as shown in FIG. 6D, processing can continue, such as by thinning back wafer 3 of bottom device 2 to expose TSVs 15, and formation of backside interconnect structure 17.

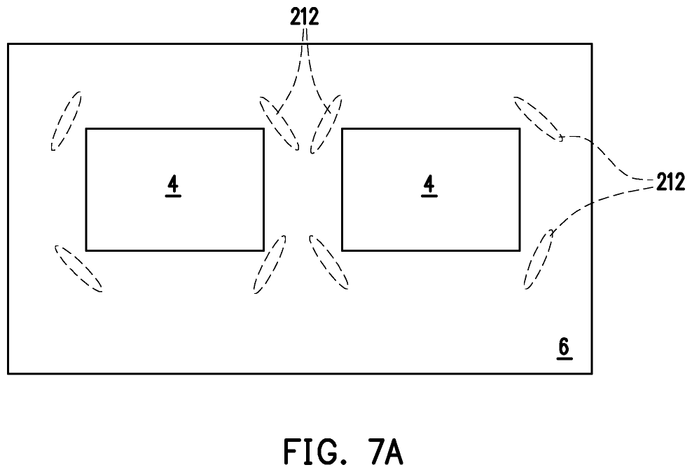

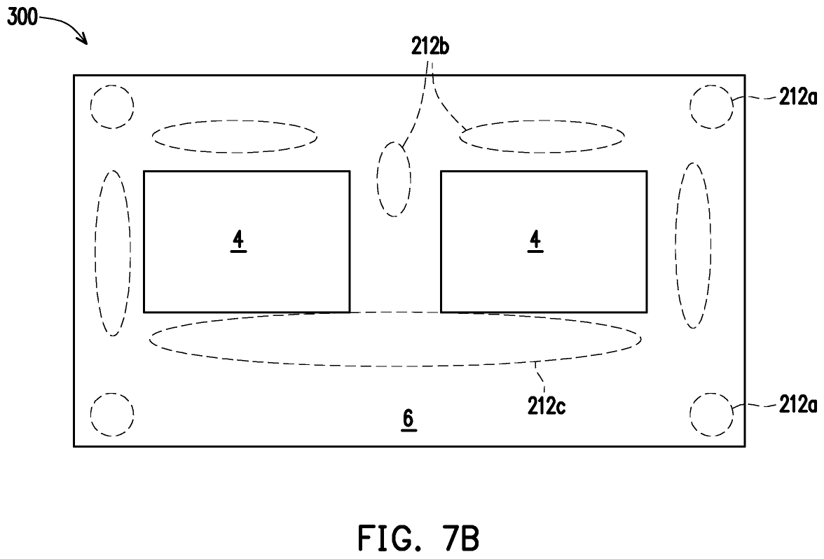

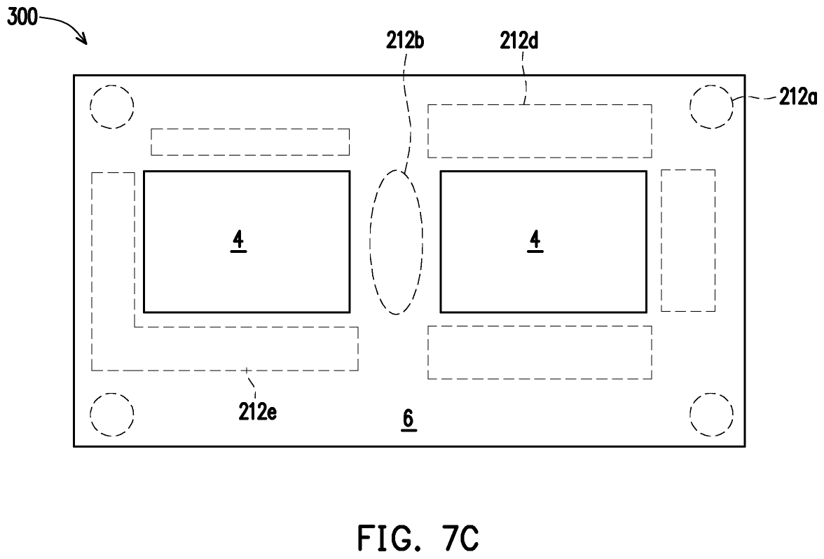

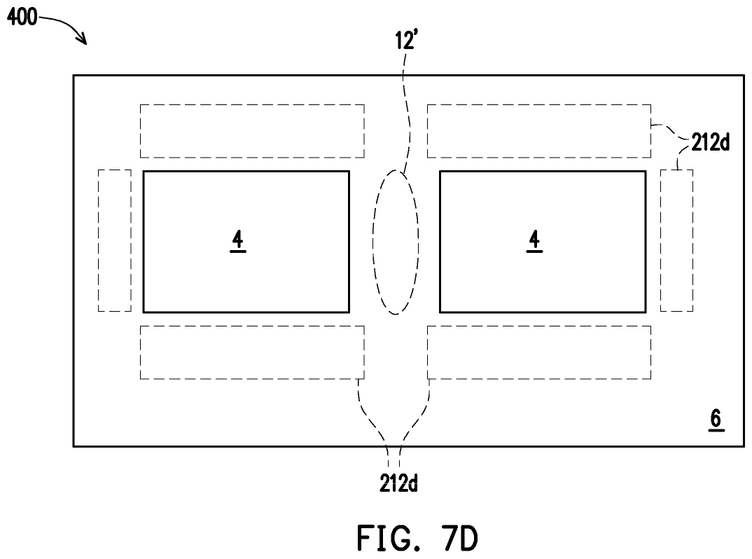

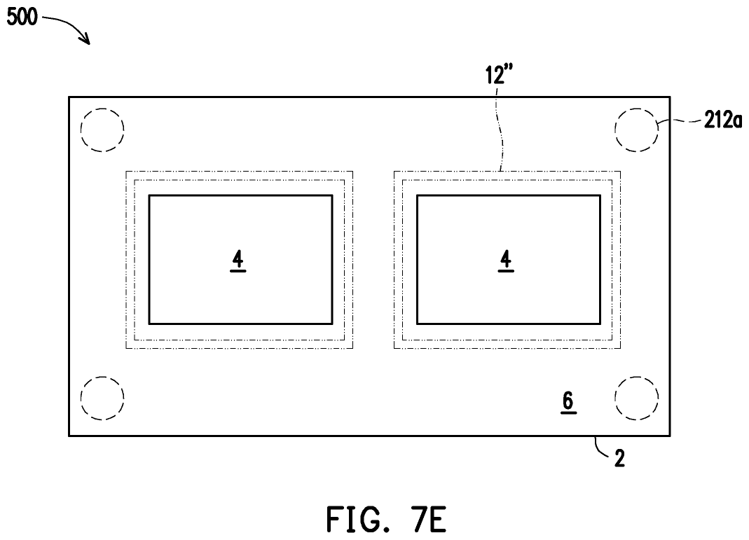

FIG. 6D illustrates only a single air gap 212 located between adjacent integrated circuit devices 4. One skilled in the art will appreciate that any number of trenches, of varying shape and locations, are within the contemplated scope of the present disclosure. For instance, in some embodiments, it may be desirable to form air gaps in particular stress-sensitive location, such as adjacent corners of integrated circuit devices 4. FIG. 7A illustrates in top down perspective, one such embodiment. The embodiment of FIG. 7A is accomplished by use of a patterned mask 24 (FIG. 6C) having respective openings that correspond to locations of respective corners of integrated circuit devices 4. These openings allow protective material 6 to be removed during an etch process, resulting in respective trenches 112 at the desired locations, which trenches become air gaps 212 as illustrated in FIG. 7A.

FIGS. 7B and 7C are also top down views of other representative package device 300 embodiments, and demonstrate that the steps described with respect to FIGS. 6A through 6D allow for increases flexibility in the size, placement, and arrangement of air gaps 212. At least in part, this is because in these embodiments, the location of the air gaps is not limited to the region of topographical irregularities (such as described with respect to FIG. 3) or the region between adjacent integrated circuit dies (such as described with respect to FIG. 5D). For instance, as illustrated in FIG. 7B, the steps of patterning trenches 112 into protective material 6 using a photomask 24 (as described with respect to FIGS. 6A through 6D), allow for air gaps to be place wherever stress is likely to incur or likely to have particularly deleterious effects. In this illustrated embodiment, air gaps 212a are formed are corners of package device 300, as these corners are likely to suffer high stress effects. Similarly, protective material 6 can be patterned to form air gaps 212b can placed along sides and between integrated circuit devices 4 to relief stress in those regions. Furthermore, protective material 6 can be patterned with trenches 112 (not shown in FIG. 7B) so that one or more air gaps 212c are formed that expose a side of one or more integrated circuit devices 4, if such exposure is desired.

Similarly, FIG. 7C illustrates that the process of patterning protective material 6 after deposition allows for air gaps 212 to be formed with different shapes, such as circular air gaps 212a, oval air gaps 212b, rectangular air gaps 212d, and irregularly shaped air gaps 212e. Effectively, the size, shape and placement of air gaps in this embodiment is limited only by limitations on the process for patterning protective material 6, such as photolithographical process limitations.

In the above-described embodiments, air gaps 12′ are formed after integrated circuit devices 4 are bonded to bottom device 2. In exemplary package device 400, illustrated in FIG. 7D, however, air gaps 12′ are formed using similar deposition processes as described above, such as by controlling the aspect ratio of the space between integrated circuit devices—while the devices are mounted on a temporary carrier substrate 22 (such as exemplary carrier substrate 22 illustrated in FIG. 6A). In this way, air gaps 12′ are formed as protective material 6 is deposited, before integrated circuit dies 4 are bonded to bottom device 2. Additionally, after protective material 6 is deposited, additional air gaps 212d (or likewise, air gaps 212a, 212b, 212c, and/or 212e, such as shown in FIGS. 7B and 7C) are formed using the processes for patterning protective material 6 to form trenches prior to bonding integrated circuit devices 4 and protective material 6 to bottom device 2 using the steps described above with respect to FIGS. 6A through 6D. By forming both air gaps 212′ and 212d (or 212a, 212b, 212c, and/or 212d) in the same packaged device, even further design flexibility and improved stress resiliency can be achieved.

Yet another exemplary package device 500 is illustrated in FIG. 7E. In this embodiment, one or more air gaps 12″ are formed using similar deposition processes as described above, such as by adjusting a deposition parameter such as the flow rate/ratio of precursor gasses during deposition of protective material 6—while the devices are mounted on a temporary carrier substrate 22 (such as exemplary carrier substrate 22 illustrated in FIG. 6A). In this way, air gaps 12″ are formed as protective material 6 is deposited, before integrated circuit dies 4 are bonded to bottom device 2. Additionally, after protective material 6 is deposited, additional air gaps 212a (or likewise, air gaps 212b, 212c, 212d, and/or 212e, such as shown in FIGS. 7B and 7C) are formed using the processes for patterning protective material 6 to form trenches prior to bonding integrated circuit devices 4 and protective material 6 to bottom device 2 using the steps described above with respect to FIGS. 6A through 6D. By forming both air gaps 212″ and 212a (or 212b, 212c, 212d, and/or 212e) in the same packaged device, even further design flexibility and improved stress resiliency can be achieved.

While the above-described embodiments using the term air gap(s), it should be recognized that air gaps 12, 212 are limited to only those spaces filled with ambient air. It is within the contemplated scope of this disclosure that air gaps 12, 212 could be filled with some other gas than air. For instance, an inert gas such as nitrogen, argon, or the like could be introduced into the deposition chamber while protective film is being deposited, in the embodiments of FIGS. 1 through 5, or could be introduced into the chamber where integrated circuit devices are being bonded to bottom device 2, in the embodiments of FIGS. 6 and 7, resulting in “air” gaps that are filled with nitrogen, argon, or the like.

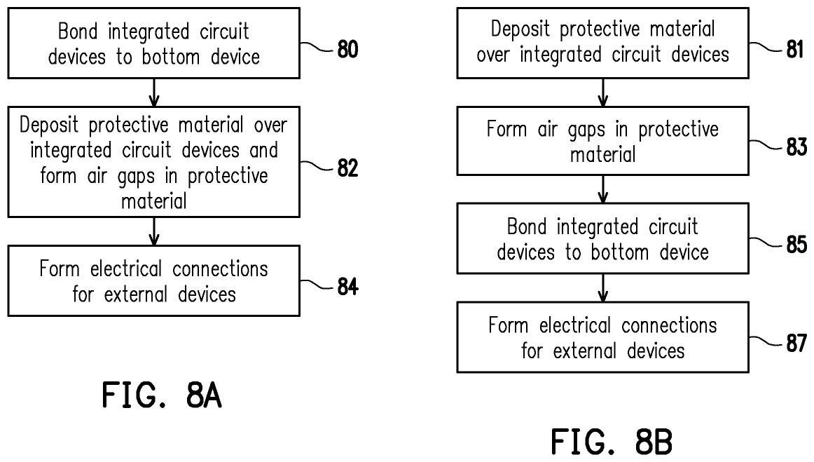

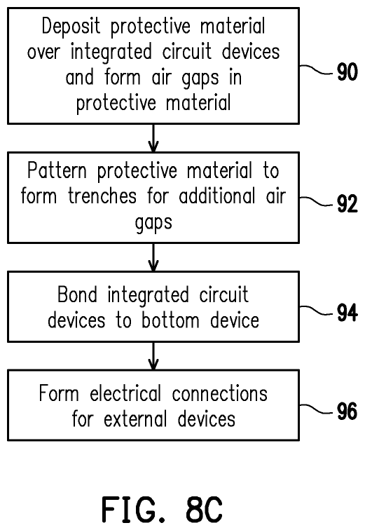

FIG. 8A is a flow chart illustrating major steps in a process embodiment, such as described with respect to the package shown in FIG. 2E. This process includes a step of bonding integrated circuit devices (4) to a bottom device 2, as shown by Step 90. Then, protective material 6 is deposited over the integrated circuit devices and air gaps 12 are formed during the deposition process, as shown by Step 82. Then, electrical connections for external components can completed, such as forming backside interconnect 17, as illustrated by Step 84.

FIG. 8B illustrates a flow chart for other embodiments, wherein protective material 6 is first deposited over integrated circuit devices 4, Step 81. Then, Step 83, air gaps 212 (or more precisely trenches 112 which become air gaps 212) are formed in protective material 6. Then, integrated circuit devices 4 are bonded to bottom device 2, Step 85. Finally, electrical connections for external components can be formed, as illustrated by Step 87.

FIG. 8C illustrates a flow chart for embodiments in which air gaps (e.g., air gaps 12′ and/or 12″) are formed during the deposition process for protective material 6 and additional air gaps (e.g., air gaps 212a, 212b, 212c, 212d, and/or 212e) are formed by patterning protective material 6 after deposition in completed. This process starts with depositing protective material 6 over integrated circuit devices 4 and forming air gaps 12, 12′, 12″ in the protective material during the deposition process, Step 90. In step 92, protective material is patterned to form trenches 112 for additional air gaps 212, 212a, 212b, 212c, 212d, 212e, Step 92. In step 94, integrated circuits 4 are bonded to bottom device 2 which process seals the trenches and forms the additional air gaps. Then, Step 96, electrical connections for external devices are formed, e.g. by forming interconnect structure 17.

One general aspect of embodiments disclosed herein includes a method of forming packaged device, the method including bonding a top die to a bottom substrate. The method also includes depositing a dielectric layer over the bottom substrate and around the top die by performing a dielectric deposition process. The device also includes forming a cavity in the dielectric layer, the cavity being adjacent at least one side of the top die, where the cavity is configured to alleviate stress on the top die arising from a coefficient of thermal expansion (CTE) mismatch between the dielectric layer and a component of the packaged device.

Another general aspect of embodiment disclosed herein includes a method of forming a packaged device, the method including mounting an integrated circuit die on a substrate. The method also includes embedding the integrated circuit die within a protective material. The method also includes forming a stress-compensating cavity within the protective material, the stress-compensating cavity being adjacent at least one side of the integrated circuit die.

Yet another general aspect of embodiments disclosed herein includes a packaged device including a bottom substrate and an integrated circuit die bonded to the bottom substrate. The device also includes a dielectric layer over the bottom substrate and at least partially surrounding the integrated circuit die. The device also includes a gas-filled cavity within the dielectric layer and adjacent at least one side of the integrated circuit die.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method of forming a packaged device, the method comprising:
bonding a top die to a bottom substrate;
depositing a dielectric layer over the bottom substrate and around the top die by performing a dielectric deposition process; and
forming a cavity in the dielectric layer, the cavity being adjacent at least one side of the top die, wherein the cavity is configured to alleviate stress on the top die arising from a coefficient of thermal expansion (CTE) mismatch between the dielectric layer and a component of the packaged device.

2. The method of claim 1, wherein the step of forming the cavity in the dielectric layer comprises:
adjusting a parameter of the dielectric deposition process, during the step of depositing the dielectric layer.

3. The method of claim 2, wherein the dielectric deposition process is performed in a deposition chamber and further wherein the parameter is a ratio of precursor gasses introduced into the deposition chamber during the dielectric deposition process.

4. The method of claim 1, wherein the step of forming the cavity in the dielectric layer comprises:
etching a trench in a surface of the dielectric layer; and
bonding the surface of the dielectric layer to a surface of the bottom substrate, simultaneously with the step of bonding the top die to the bottom substrate.

5. The method of claim 4, further comprising filling the trench with an gas prior to the step of bonding the surface of the dielectric layer to the surface of the bottom substrate, the gas being selected from the group consisting of air, nitrogen, an inert gas, and noble gas, and combinations of same.

6. The method of claim 1, further comprising forming the cavity in the dielectric layer to surround the top die.

7. The method of claim 6, further comprising forming the cavity in the dielectric layer adjacent and laterally displaced from each side of the top die.

8. A method of forming a packaged device, the method comprising:
mounting an integrated circuit die on a substrate;
embedding the integrated circuit die within a protective material; and
forming a stress-compensating cavity within the protective material, the stress-compensating cavity being adjacent at least one side of the integrated circuit die.

9. The method of claim 8, wherein the stress-compensating cavity is formed within the protective material during the step of embedding the integrated circuit die within the protective material.

10. The method of claim 9, wherein the protective material is formed by a deposition process within a deposition chamber, and further wherein the stress-compensating cavity is formed by adjusting a ratio of precursor gasses in the deposition chamber during the deposition process.

11. The method of claim 8, further comprising planarizing a top surface of the protective material to be level with a top surface of the integrated circuit die.

12. The method of claim 8, further comprising filling the stress-compensating cavity with a gas selected from the group consisting of air, an inert gas, a noble gas, nitrogen, and combinations of same.

13. The method of claim 8, further comprising direct bonding the integrated circuit die to the substrate.

14. The method of claim 8, wherein the stress-compensating cavity is formed to expose at least one side of the integrated circuit die.

15. The method of claim 8, wherein the step of embedding the integrated circuit die within the protective material includes depositing the protective material around the integrated circuit die.

16. The method of claim 8, wherein the stress-compensating cavity is configured to deform in shape in response to thermal expansion of the protective material.

17. The method of claim 8, further comprising:
mounting a bottom surface of the integrated circuit die to a carrier;
forming the stress-compensating cavity adjacent a top surface of the integrated circuit die;
bonding the top surface of the integrated circuit die to the substrate; and
removing the carrier from the bottom surface of the integrated circuit die.

18. A packaged device including:
a bottom substrate;
an integrated circuit die bonded to the bottom substrate;
a dielectric layer over the bottom substrate and at least partially surrounding the integrated circuit die; and
a gas-filled cavity within the dielectric layer and adjacent at least one side of the integrated circuit die.

19. The packaged device of claim 18, wherein the gas-filed cavity is formed adjacent a corner of the integrated circuit die.

20. The packaged device of claim 18, wherein the gas-filled cavity is filed with a fluid selected from the group consisting of air, nitrogen, a noble gas, an inert gas, and combinations of same.
